(19) United States
(12) Patent Application Publication
(10) Pub. No.: US 2013/0201398 A1
(43) Pub. Date: Aug. 8, 2013

(54) MIXER AND MULTICHANNEL AUDIO INTERFACE FOR A TABLET COMPUTER

(71) Applicant: ALESIS, L.P., Cumberland, RI (US)

(72) Inventors: Daniel I. Radin, New York, NY (US); David C. Gill, North Providence, RI (US)

(73) Assignee: ALESIS, L.P., Cumberland, RI (US)

(21) Appl. No.: 13/628,760

(22) Filed: Sep. 27, 2012

Related U.S. Application Data
(60) Provisional application No. 61/594,028, filed on Feb. 2, 2012.

(51) Int. Cl. H04B 1/00; H03G 3/00; H04N 5/268; H04R 5/00

(52) U.S. Cl. 348/552; 381/119; 381/1; 381/109; 348/E05.057

(57) ABSTRACT

A mixer for a touchscreen device is disclosed. The mixer includes a body. A dock on the body is configured and arranged to receive a touchscreen device therein. The mixer also includes a number of audio inputs and a main audio output. An integrated data interface is configured and arranged to connect to the touchscreen device. An audio codec processor configured and arranged to receive audio through the audio inputs and selectively route mixed audio to the main audio output and through the integrated data interface to the touchscreen device.

### CROSS-REFERENCE TO RELATED APPLICATION

This patent document claims priority to earlier filed U.S. Provisional Patent Application Ser. No. 61/594,028, filed on Feb. 2, 2012, the entire contents of which are incorporated herein by reference.

### BACKGROUND

1. Technical Field

The present patent document relates generally to audio mixers and more particularly to an audio mixer and multichannel recorder configured for tablet computers.

2. Background of the Related Art

Audio mixers are well known in the art. However these prior art audio mixers have limited capability to interact with modern tablet computers. Accordingly, there is a perceived need in the industry for an audio mixer capable of pro-level audio mixing that has integrated tablet computer connectivity.

### SUMMARY

The present invention solves the problems of the prior art by providing an audio mixer that includes integrated tablet computer dock for seamless operation with a tablet computer. The audio mixer, as described herein, includes four or more channels of audio input. The channels are set up as a standard audio mixer. They can be mixed into 1 (mono) or 2 channels and fed to the tablet computer for processing or recording. Additionally, each channel can be independently transmitted to the tablet computer for software applications that allow Multi-channel recording or processing.

The audio mixer is designed to operate as a standard audio mixer when the tablet computer is removed. That is, the audio mix can be routed direct to the outputs. All settings, filtering and processing internal to the audio mixer are not affected when the tablet computer is not present in the dock.

One of the inputs may also be used with calibrated microphone. This enables the audio mixer to be used with applications utilizing real time audio analyzers.

### BRIEF DESCRIPTION OF THE DRAWINGS

These and other features, aspects, and advantages of the present invention will become better understood with reference to the following description, appended claims, and accompanying drawings where:

FIG. 1 is a perspective view of the mixer;

FIG. 2 is a partial top view of the control area of the mixer;

FIG. 3 is a rear view of the mixer;

FIG. 4 is a perspective view of the mixer with a tablet computer seated within a dock;

FIG. 5 is a perspective view of the mixer with a door to the dock open and the tablet computer being removed therefrom;

FIG. 6 is a schematic diagram of the input channels of the mixer; and

FIG. 7 is a schematic diagram of the operation of the mixer.

### DESCRIPTION OF THE PREFERRED EMBODIMENT

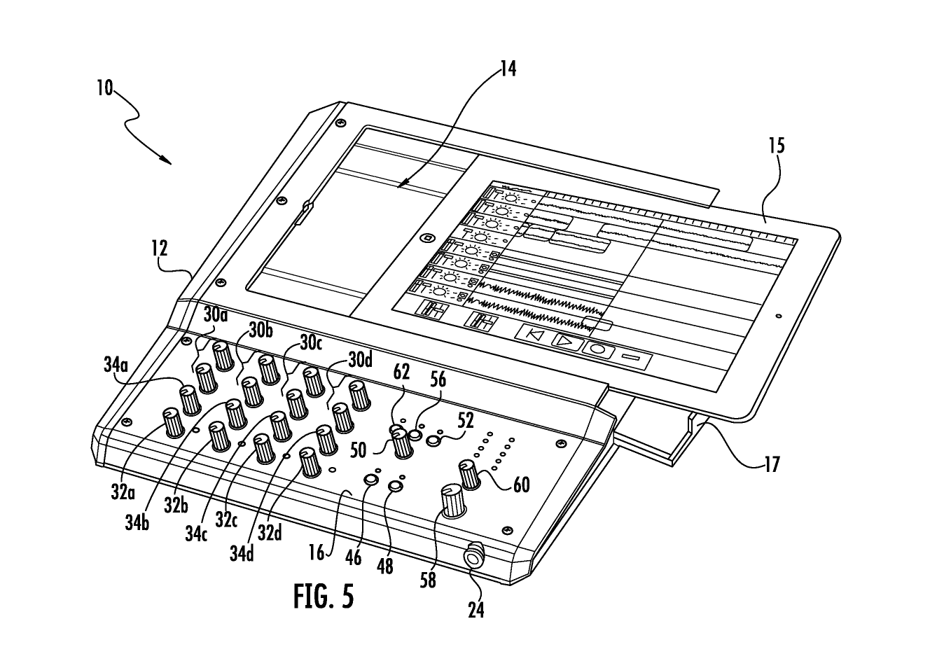

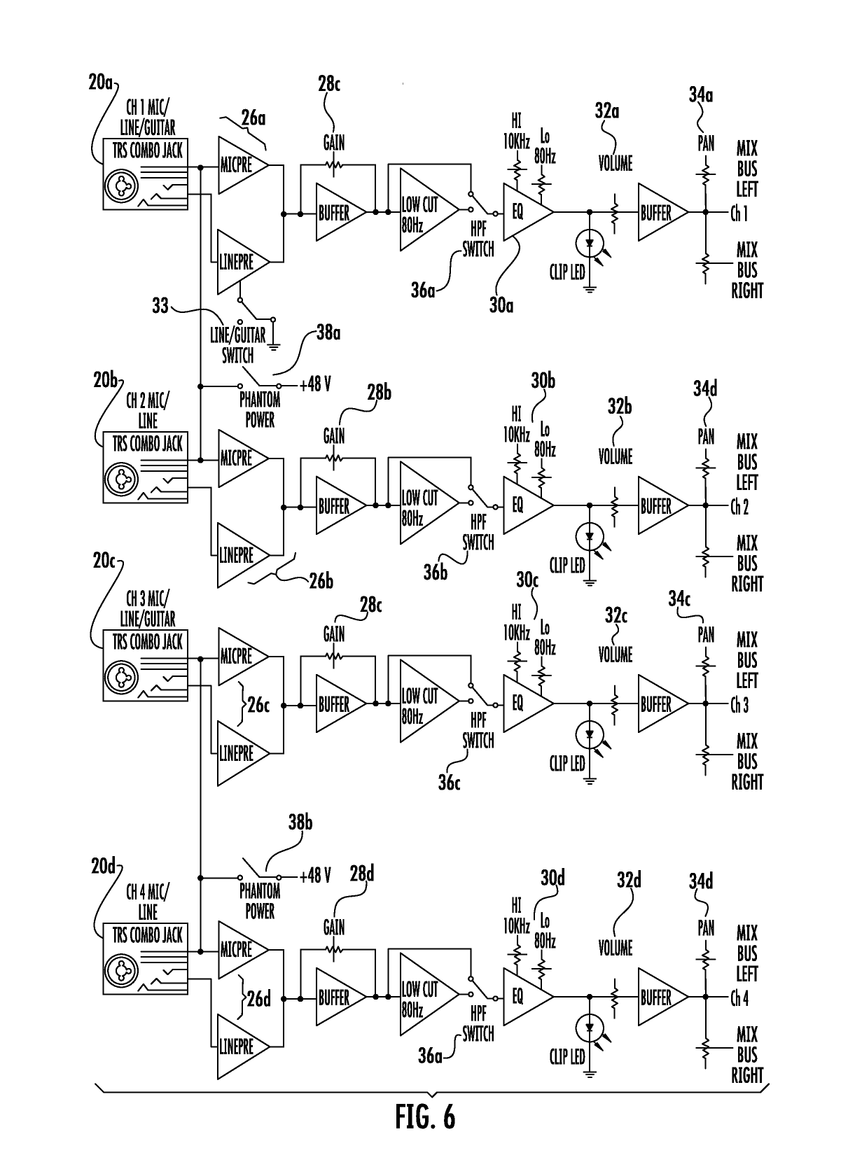

Referring now to FIGS. 1-5, a preferred embodiment of the audio mixer is shown generally at 10. The audio mixer 10 includes a body 12 with a dock 14 or cavity configured and arranged to receive a tablet computer 15 therein. Extending from the dock 10 is a control console 16 that includes various controls for affecting the audio mix of the audio mixer 10. The rear panel 18 of the audio mixer 10 includes inputs for up to four channels 20a-d of audio as shown, but additional channels may be added as is known in the art.

The rear panel 18 also includes output connectors 22 to route the audio mix to other audio recording, processing or playing devices. A headphone output 24 is provided on the control console 16 for the convenience of the user. The proper industry-standard connectors are provided to interface with mics, ¼″ cables, RCA cables, XLR cables, and the like. Additional outputs 22 may be included to provide outputs for other uses such as monitor and control room, for example, as is known in the art. The outputs 22 may include additional redundant connectors in industry-standard styles for the convenience of the user.

The tablet computer 15 is secured within the dock 14 via a door 17 that is hinged to the body 12 of the mixer 10.

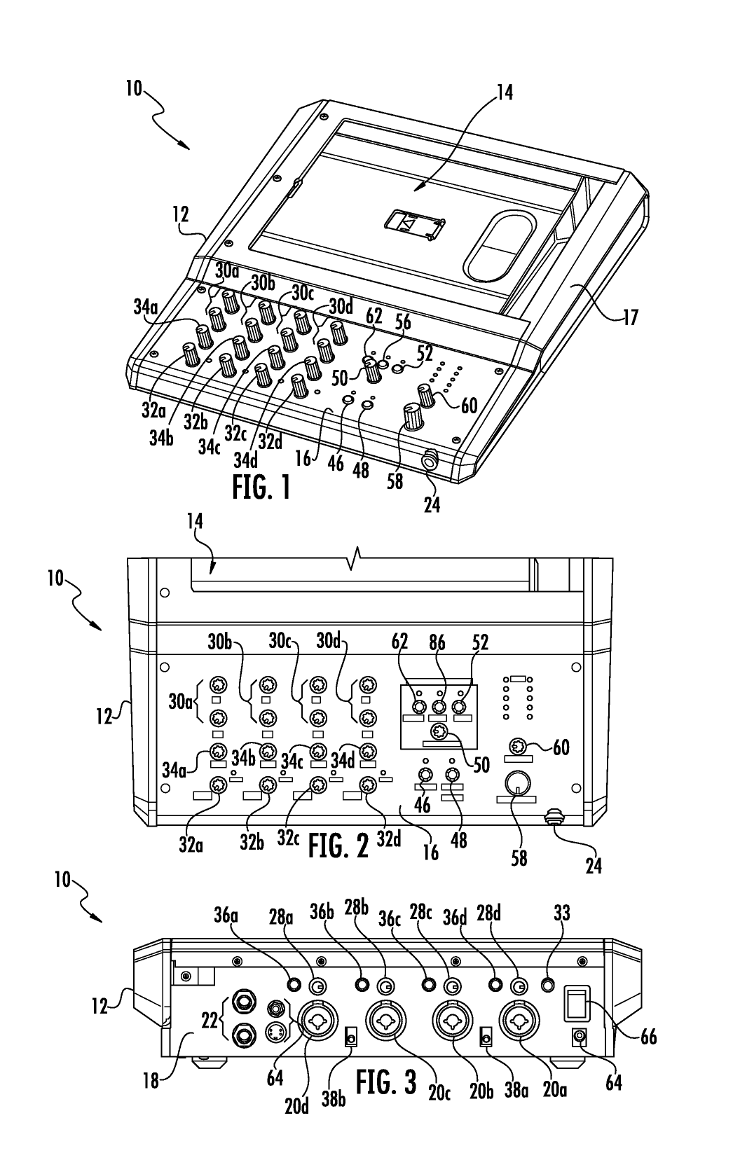

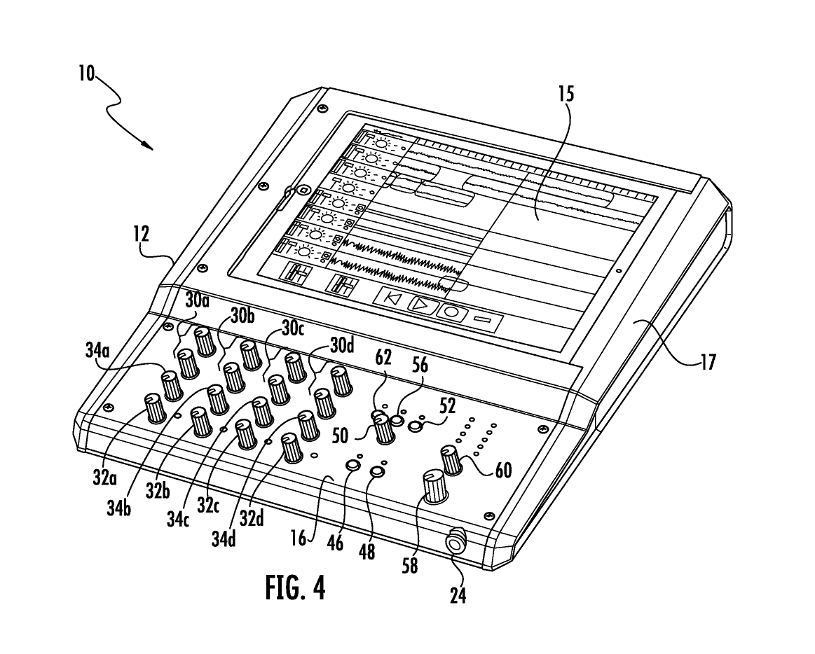

Referring to FIG. 6, each channel input 20 may include pre-amplifiers 26, gain control 28, equalizer controls 30, volume controls 32, and pan control 34. Each channel may be selectively deactivated as well. These controls are located in the control console 16 or rear panel 18 of the body 12 of the audio mixer 10, best seen in FIG. 2. Each channel input 20 may also include a high pass filter that can be selectably enabled via a HPF switch 36.

A guitar/line switch 33 may be provided to route audio of unamplified guitars.

Phantom power may be applied to channel inputs one 20a and two 20b and channel inputs three 20c and four 20d via phantom power switches 38a, 38b, respectively. The phantom power switches 38 apply 48V to the channel inputs 20 for use with studio condenser microphones.

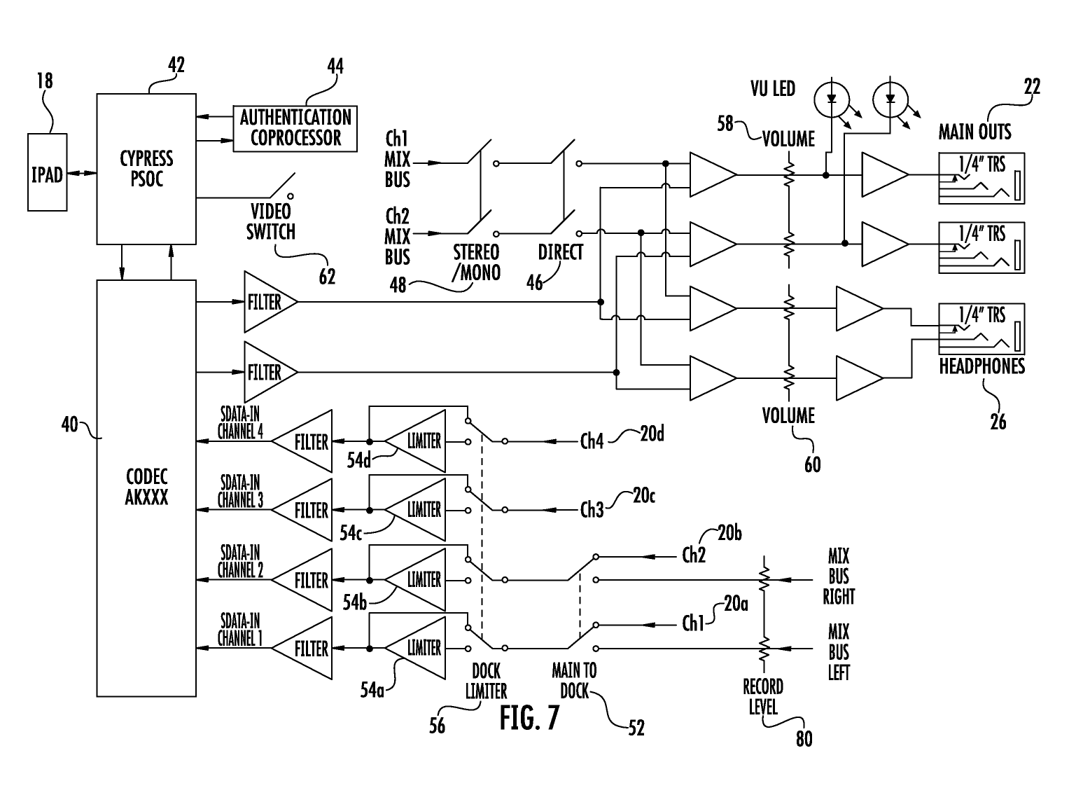

Referring to FIG. 7, the four channels 20 of audio are routed into an audio codec processor 40, which may route the audio to the tablet computer 15 for additional processing and/or recording. Connectivity with the tablet computer 15 may be established through an industry standard data interface, such as a USB. An integrated data interface 42 is provided to communicate and transmit audio signals to the tablet computer 15. The interface can then send or receive digital audio signals to and from Digital to Audio Converter chips (DACs), Audio to Digital Converters (ADCs), or Digital Audio Chips to convert to SPDIF, ADAT Optical, or other digital audio format as desired. In the case of Apple brand tablet computers, an authentication coprocessor 44 is connected to the integrated data interface to enable USB communications.

As shown in FIGS. 2 and 4, by way of example, channels one (Ch 1) 20a and two (Ch 2) 20b may be routed directly to the main outputs 22 via a direct switch 46 on the control console. Stereo or mono output may be toggled via a stereo/mono switch 48 as well.

A recording level control 50 is included to control the audio level of the channel inputs 20.

Engaging mix switch 52 enables audio from the channel inputs 20 to be routed as a single audio source rather than as individual channels. A limiter 54 may be engaged via a limiter switch 56.

A master volume control 58 is included to control the overall audio output level as well as a separate headphone volume control 60 for controlling the level of the headphone output 24. If additional outputs are provided, additional level controls may also be included to control the level of that particular output as is known in the art.

Optionally, video from the tablet computer 15 may be enabled via a video switch 62, which outputs video from the tablet computer 15 to video outputs 64 on the rear panel 18 of the main body 12 of the mixer 10.

A power input 64 supplies power to the mixer 10. A power switch 66 is also provided to deactivate the mixer 10.

One advantage of the mixer 10 is the ability to function as an audio mixer with or without the tablet computer 15 engaged in the dock 14. With the tablet computer 15 engaged in the dock 15, additional audio processing and recording may be performed on the channel inputs 20. However, without a tablet computer 15 engaged in the dock 14, audio form the channel inputs 20 may be mixed and routed to the main audio outputs 22.

It would be appreciated by those skilled in the art that various changes and modifications can be made to the illustrated embodiments without departing from the spirit of the present invention. All such modifications and changes are intended to be within the scope of the present invention.

What is claimed is:

1. A mixer for a touchscreen device, comprising:
a body;
a dock on the body configured and arranged to receive a touchscreen device therein;
a plurality of audio inputs;
a main audio output;
an integrated data interface configured and arranged to connect to the touchscreen device; and
an audio codec processor configured and arranged to receive audio through the plurality of audio inputs and selectively route mixed audio to the main audio output and through the integrated data interface to the touchscreen device.

2. The mixer of claim 1, wherein there are four audio inputs.

3. The mixer of claim 1, further comprising a headphone output electrically connected to the main audio output.

4. The mixer of claim 1, further comprising a master volume control configured and arranged to selectively controlling the level of the main audio output.

5. The mixer of claim 1, further comprising a stereo/mono switch configured and arranged to switch the audio of the main audio output between stereo audio and mono audio.

6. The mixer of claim 1, wherein each audio input includes a gain control.

7. The mixer of claim 1, wherein each audio input includes equalizer controls.

8. The mixer of claim 1, wherein each audio input includes a volume control.

9. The mixer of claim 1, wherein each audio input is configured and arranged to be selectively deactivated.

10. The mixer of claim 1, further comprising a guitar/line switch electrically connected to one of the plurality of audio inputs.

11. The mixer of claim 1, further comprising a door closing the dock, the door hinged to the body.

12. The mixer of claim 1, wherein each audio input includes a switchable high pass filter.

13. The mixer of claim 1, wherein each audio input includes a gain control.

14. The mixer of claim 1, further comprising a phantom power switch configured and arranged to apply phantom power to an audio input.

15. The mixer of claim 1, further comprising a video switch and a video output on the body, the video switch configured and arranged to route video from the touchscreen device to the video output.
